(19) United States
(12) Patent Application Publication
(10) Pub. No.: US 2025/0044321 A1
(43) Pub. Date: Feb. 6, 2025

(54) CONTACT PIN ASSEMBLY FOR KELVIN TEST AND KELVIN TEST DEVICE COMPRISING SAME

(71) Applicant: POINT ENGINEERING CO., LTD., Chungcheongnam-do (KR)

(72) Inventors: Bum Mo AHN, Gyeonggi-do (KR); Young Heum EOM, Gyeonggi-do (KR); Sin Seok HAN, Gyeonggi-do (KR)

(73) Assignee: POINT ENGINEERING CO., LTD., Chungcheongnam-do (KR)

(21) Appl. No.: 18/717,410

(22) PCT Filed: Dec. 5, 2022
(86) PCT No.: PCT/KR2022/019608

§ 371 Date: Jun. 6, 2024

(30) Foreign Application Priority Data
Dec. 10, 2021 (KR) 10-2021-0176253

(51) Int. Cl. G01R 1/067; G01R 1/073

(52) U.S. Cl. CPC G01R 1/06722; G01R 1/06761; G01R 1/07307

(57) ABSTRACT

The present invention provides an electrically conductive contact pin for a Kelvin test and a test device comprising same, which can cope with the narrower pitch between electrodes of a semiconductor device.

### TECHNICAL FIELD

The present disclosure relates to a contact pin assembly for a Kelvin test and a Kelvin test device including the same.

### BACKGROUND ART

Among semiconductor tests, a Kelvin test is used to precisely measure the resistance of a semiconductor device. A Kelvin test device is arranged so that a pair of electrically conductive contact pins are located between and connected to one electrode of a semiconductor device and two lands of a circuit board.

As a Kelvin test device, a pogo-pin type contact pin is generally used. A pogo-pin type contact pin includes an upper plunger connected to an electrode of a semiconductor device, a lower plunger connected to a land of a circuit board, a cylindrical barrel in which the upper plunger and/or the lower plunger is inserted, and an elastic spring housed in the barrel to provide an elastic force. A contact pin measures the resistance of a semiconductor device while being inserted into a through hole of a housing.

However, the Kelvin test device according to the related art has the following problems.

First, the pogo-pin type contact pin has limitations in reducing the pitch between two electrodes due to characteristics of a cylindrical barrel structure that houses the elastic spring and of a structure of the elastic spring. Specifically, at a time when recent semiconductor devices are gradually highly integrated and pitch between the electrodes of the semiconductor device is slightly decreased, it is difficult to reduce the entire size of the pogo-pin type contact pin. Therefore, there is a problem in that the pogo-pin type contact pin cannot cope with the high integration of semiconductor devices.

Furthermore, two contact pins are brought into contact with one electrode of the semiconductor device and each contact pin is inserted into each through hole. Therefore, two through holes are required for one electrode of the semiconductor device. As the pitch between the electrodes becomes narrower, the internal width of the through hole should also become smaller, and a distance of a wall portion between the through holes becomes smaller. Accordingly, there is a problem in that it is difficult to secure the rigidity of a housing.

### DOCUMENTS OF RELATED ART

### Patent Document

(Patent Document 1) Korean Patent No. 10-0915654

### DISCLOSURE

### Technical Problem

Accordingly, the present disclosure has been made keeping in mind the above problems occurring in the related art, and an objective of the present disclosure is to provide a contact pin assembly for a Kelvin test and a Kelvin test device including the same, the contact pin assembly being capable of cope with the narrower pitch between electrodes of a semiconductor device.

### Technical Solution

According to an aspect of the present disclosure, there is provided a contact pin assembly for a Kelvin test electrically connected to one electrode provided at an inspection object and two lands provided at the circuit board, respectively, the contact pin assembly including: a first electrically conductive contact pin; a second electrically conductive contact pin; and an insulating part provided between the first electrically conductive contact pin and the second electrically conductive contact pin and insulating the first electrically conductive contact pin and the second electrically conductive contact pin from each other.

The insulating part may include: a surface insulating part provided on at least one of upper and lower surfaces of at least one of the first and second electrically conductive contact pins; and a side surface insulating part provided between the first electrically conductive contact pin and the second electrically conductive contact pin, wherein the surface insulating part and the side surface insulating part may be formed to be integrally connected to each other.

The contact pin assembly may include: a micro trench provided on a side surface of the first electrically conductive contact pin and a side surface of the second electrically conductive contact pin, the surfaces being in contact with the insulating part.

The micro trench may have a corrugated shape composed of a hill and a valley with a depth greater than or equal to 20 nm and less than or equal to 1 μm, the hill and the valley being repeated along the side surfaces of the first electrically conductive contact pin and the second electrically conductive contact pin.

Each of the first electrically conductive contact pin and the second electrically conductive contact pin may be formed of a plurality of metal layers stacked in a thickness direction of each electrically conductive contact pin.

Each of the first electrically conductive contact pin and the second electrically conductive contact pin may include: a first plunger; a second plunger; an elastic part enabling the first plunger and the second plunger to be elastically displaced; and a support part guiding the elastic part so that the elastic part may be compressed and stretched in a longitudinal direction of the contact pin assembly for a Kelvin test, wherein the insulating part may be provided between the support part provided in the first electrically conductive contact pin and the support part provided in the second electrically conductive contact pin.

The elastic part may include: a first elastic part connected to the first plunger; a second elastic part connected to the second plunger; and a middle fixation part connected to the first elastic part and the second elastic part while being located between the first elastic part and the second elastic part, and provided integrally with the support part, wherein the insulating part may include: a surface insulating part provided on at least one of upper and lower surfaces of at least one of the middle fixation part of the first electrically conductive contact pin and the middle fixation part of the second electrically conductive contact pin; and a side surface insulating part provided between the first electrically conductive contact pin and the second electrically conductive contact pin.

The insulating part may be thermoplastic polyimide.

Meanwhile, a Kelvin test device according to the present disclosure may include: a contact pin assembly for a Kelvin test, the contact pin assembly including a first electrically conductive contact pin, a second electrically conductive contact pin, and an insulating part provided between the first electrically conductive contact pin and the second electrically conductive contact pin and insulating the first electrically conductive contact pin and the second electrically conductive contact pin from each other; and a support plate in which a housing hole housing the contact pin assembly for a Kelvin test may be formed.

A section of the housing hole may be a quadrilateral shape, and in order to prevent the contact pin assembly for a Kelvin test from being rotated while being inserted in the housing hole, an outer shape of a section of the contact pin assembly for a Kelvin test may be a quadrilateral shape corresponding to the shape of the housing hole.

### Advantageous Effects

The present disclosure provides a contact pin assembly for a Kelvin test and a Kelvin test device including the same, which can cope with the narrower pitch between electrodes of a semiconductor device.

### DESCRIPTION OF DRAWINGS

FIG. 1 is a perspective view illustrating a contact pin assembly for a Kelvin test according to an exemplary first embodiment of the present disclosure.

FIG. 2 is a view illustrating a Kelvin test using the contact pin assembly for a Kelvin test according to the exemplary first embodiment of the present disclosure.

FIGS. 3a to 15b are views illustrating a method for manufacturing the contact pin assembly for a Kelvin test according to the exemplary first embodiment of the present disclosure.

FIGS. 16a and 16b are views illustrating a modification of the contact pin assembly for a Kelvin test according to the exemplary first embodiment of the present disclosure.

FIGS. 17a and 17b are views illustrating a modification of the contact pin assembly for a Kelvin test according to the exemplary first embodiment of the present disclosure.

FIG. 18a is a plan view illustrating the contact pin assembly for a Kelvin test according to an exemplary second embodiment of the present disclosure.

FIG. 18b is a sectional view illustrating taken alone line A-A′ of FIG. 18a.

FIG. 19 is a perspective view illustrating the contact pin assembly for a Kelvin test according to the exemplary second embodiment of the present disclosure.

FIG. 20 is a view illustrating only a pair of electrically conductive contact pins of the contact pin assembly for a Kelvin test according to the exemplary second embodiment of the present disclosure.

FIG. 21 is a view illustrating a Kelvin test using the contact pin assembly for a Kelvin test according to the exemplary second embodiment of the present disclosure.

### MODE FOR INVENTION

Hereinbelow, the following illustrates the principle of the present disclosure. Those skilled in the art will be able to embody the principle of the present disclosure and invent various apparatuses included in the spirit and the scope of the present disclosure, although not shown herein. Further, all conditional terms and embodiments described herein are clearly intended for the purpose of understanding the concept of the present disclosure, and should be understood not to be limited to the specifically listed embodiments and states.

The above and other objectives, features and advantages of the present disclosure will be more clearly understood from the following detailed description taken in conjunction with the accompanying drawings.

The embodiments described herein will be described with reference to sectional views and/or perspective views, which are ideal drawings of the present disclosure. The thicknesses of films and regions illustrated in the drawings are exaggerated for an effective description of the technical sprit of the present disclosure. Variations from the shapes of the illustrations as a result, for example, of manufacturing techniques and/or tolerances, are to be expected. Furthermore, the number of metal moldings illustrated in the drawings is illustrative, and only a portion thereof is illustrated in the drawings. Therefore, the embodiments of the present disclosure are not limited to the specific forms shown in the drawings, but include the changes in the forms caused by manufacturing processes. The technical terms used in the specification are used to describe specific embodiments, and thus are not intended to limit the present disclosure. The singular expressions are intended to include the plural expressions unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Hereinafter, exemplary embodiments of the present disclosure will be described in detail with reference to the accompanying drawings. Hereinafter, in describing various embodiments, the same names and the same reference numbers will be used to refer to components that perform the same function even when the embodiments are different. Furthermore, configuration and operation already described in other embodiments will be omitted for convenience.

### First Embodiment

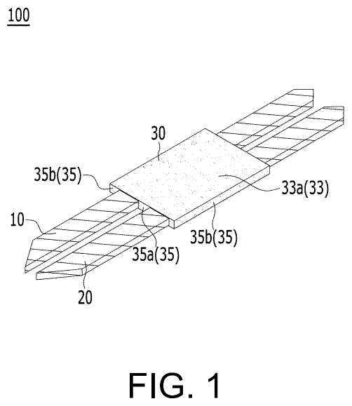

Hereinafter, referring to FIGS. 1 to 15b, a contact pin assembly for a Kelvin test according to an exemplary first embodiment of the present disclosure will be described.

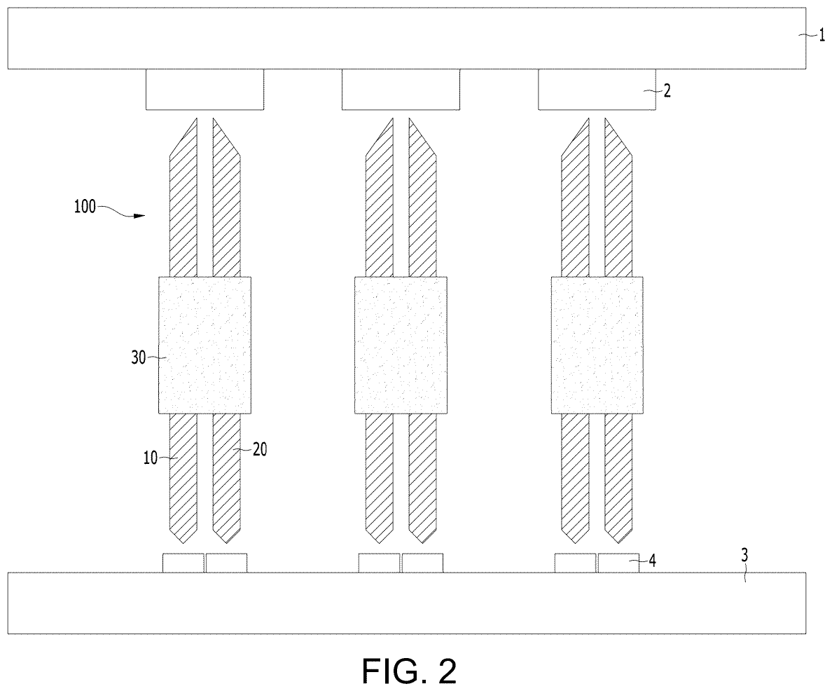

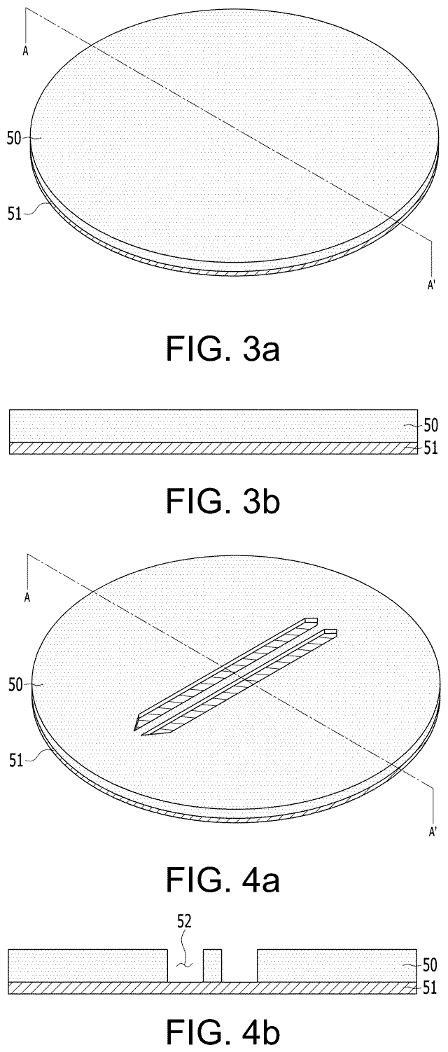

FIG. 1 is a perspective view of a contact pin assembly for a Kelvin test according to an exemplary first embodiment of the present disclosure. FIG. 2 is a view illustrating a Kelvin test using the contact pin assembly for a Kelvin test according to the exemplary first embodiment of the present disclosure. FIGS. 3a to 15b are views illustrating a method for manufacturing the contact pin assembly for a Kelvin test according to the exemplary first embodiment of the present disclosure.

The contact pin assembly 100 for a Kelvin test according to the first embodiment is electrically connected to one electrode 2 provided at an inspection object 1 and two lands 4 provided at a circuit board 3.

According to the first embodiment, the contact pin assembly 100 for a Kelvin test includes a first electrically conductive contact pin 10, a second electrically conductive contact pin 20, and an insulating part 30. The insulating part 30 is provided between the first electrically conductive contact pin 10 and the second electrically conductive contact pin 20 and insulates the first electrically conductive contact pin 10 and the second electrically conductive contact pin 20 from each other.

An upper portion of the first electrically conductive contact pin 10 and an upper portion of the second electrically conductive contact pin 20 are connected identically to one electrode provided at the inspection object, and lower portions thereof are connected to respective lands provided at the circuit board. Accordingly, the resistance of the inspection object is precisely measured.

The first electrically conductive contact pin 10 and the second electrically conductive contact pin 20 may be formed of at least one metal selected from rhodium (Rd), platinum (Pt), iridium (Ir), palladium (Pd), nickel (Ni), manganese (Mn), tungsten (W), phosphorus (Ph), or an alloy thereof, or a palladium-cobalt (PdCo) alloy, a palladium-nickel (PdNi) alloy or a nickel-phosphorus (NiPh) alloy, a nickel-manganese (NiMn), a nickel-cobalt (NiCo), or a nickel-tungsten (NiW) alloy, copper (Cu), silver (Ag), gold (Au), or an alloy thereof.

The first electrically conductive contact pin 10 and the second electrically conductive contact pin 20 are arranged in a transversely symmetric form based on the insulating part 30.

The insulating part 30 simultaneously has a coupling function of coupling the first electrically conductive contact pin 10 and the second electrically conductive contact pin 20 integrally with each other and an insulating function of insulating the first electrically conductive contact pin 10 and the second electrically conductive contact pin 20 from each other.

The insulating part 30 is thermoplastic polyimide (TPI), and thermoplastic polyimide includes hardened resin composition for forming thermoplastic polyimide including one or more types of resins selected from a group consisting of polyimide, polyamide, polyamide-imide, and polyamic acid resin. However, a material of the insulating part 30 is not limited thereto and may include any material that can achieve both the coupling function and the insulating function of the first electrically conductive contact pin 10 and the second electrically conductive contact pin 20 at the same time.

The insulating part 30 is formed to entirely wrap each of the first electrically conductive contact pin 10 and the second electrically conductive contact pin 20 in partial areas between opposite ends of each of the first electrically conductive contact pin 10 and the second electrically conductive contact pin 20. As a result, in the region with the insulating part 30, the partial area of each of the first electrically conductive contact pin 10 and the second electrically conductive contact pin 20 is not exposed.

The insulating part 30 includes a surface insulating part 33 and a side surface insulating part 35. The surface insulating part 33 and the side surface insulating part 35 are formed to be integrally connected to each other.

The surface insulating part 33 is provided on at least one of the upper and lower surfaces of at least one of the first and second electrically conductive contact pins 10 and 20. The surface insulating part 33 includes an upper surface insulating part 33a and a lower surface insulating part 33b. The upper surface insulating part 33a is provided on an upper surface of at least one of the first and second electrically conductive contact pins 10 and 20. The lower surface insulating part 33b is provided on a lower surface of at least one of the first and second electrically conductive contact pins 10 and 20.

The side surface insulating part 35 includes an inside surface insulating part 35a and an outside surface insulating part 35b. The inside surface insulating part 35a is provided between the first electrically conductive contact pin 10 and the second electrically conductive contact pin 20. The outside surface insulating part 35b is provided on an outside surface opposite to the inside surface insulating part 35a.

As illustrated in FIGS. 1 and 2, the insulating part 30 includes the upper surface insulating part 33a provided on the upper surface of each of the first electrically conductive contact pin 10 and the second electrically conductive contact pin 20, the lower surface insulating part 33b provided on the lower surface of each of the first electrically conductive contact pin 10 and the second electrically conductive contact pin 20, the inside surface insulating part 35a provided on each surface between the first electrically conductive contact pin 10 and the second electrically conductive contact pin 20, and the outside surface insulating part 35b provided on each outside surface opposite to the inside surface insulating part 35a.

The upper surface insulating part 33a, the lower surface insulating part 33b, the inside surface insulating part 35a, and the outside surface insulating part 35b are connected to each other to be integrated. The inside surface insulating part 35a performs the insulating function to insulate the first electrically conductive contact pin 10 and the second electrically conductive contact pin 20 from each other. The surface insulating part 33 integrated with the inside surface insulating part 35a performs the coupling function for the first electrically conductive contact pin 10 and the second electrically conductive contact pin 20. The outside surface insulating part 35b integrated with the surface insulating part 33 performs the coupling function for the first electrically conductive contact pin 10 and the second electrically conductive contact pin 20.

Hereinafter, referring to FIGS. 3a to 15b, a method 100 for manufacturing the contact pin assembly for a Kelvin test according to the exemplary first embodiment of the present disclosure will be described.

First, the method is performed by preparing a mold 50 of an anodic oxide film material with a seed layer 51 provided at a lower portion thereof.

FIG. 3a is a view illustrating the mold 50 of an anodic oxide film material with the seed layer 51 provided at the lower portion of the mold, and FIG. 3b is a sectional view taken along line A-A′ of FIG. 3a.

An anodic oxide film is a film formed by anodizing a parent metal, and each pore is a hole formed during the process of forming an anodic oxide film by anodizing a parent metal. For example, when a parent metal is aluminum (Al) or an aluminum alloy, when a parent metal is anodized, an anodic oxide film of aluminum oxide film (Al2O3) material is formed on a surface of the parent metal. However, a parent metal is not limited thereto and includes Ta, Nb, Ti, Zr, Hf, Zn, W, Sb, or an alloy thereof. The anodic oxide film formed as described above is vertically divided into a barrier layer in which pores are not formed, and a porous layer in which pores are formed. When the parent metal is removed from the parent metal on which the anodic oxide film with the barrier layer and the porous layer is formed on the surface thereof, only the anodic oxide film of aluminum oxide (Al2O3) material remains. The anodic oxide film may be formed into a penetrated structure formed vertically through each pore without the barrier layer formed during anodizing or a structure in which the barrier layer formed during anodizing remains and blocks either of upper or lower end portion of each pore.

The anodic oxide film has a 2˜3 ppm/° C. coefficient of thermal expansion. Accordingly, when the anodic oxide is exposed to a high-temperature environment, the thermal deformation due to the temperature is less. Therefore, even when the contact pin assembly 100 for a Kelvin test is manufactured in a high-temperature environment, the contact pin assembly 100 for a Kelvin test can be precisely manufactured without thermal deformation.

According to the embodiment of the present disclosure, the contact pin assembly 100 for a Kelvin test is manufactured using the mold 50 of an anodic oxide film material instead of a photoresist mold. In this aspect, there are effects on the shape precision and the realization of a micro shape which have limitations when implemented with the photoresist mold. Furthermore, a conventional photoresist mold is used to manufacture a probe pin with a level of 40 μm thickness. However, the mold 50 of an anodic oxide film material may be used to manufacture the contact pin assembly 100 for a Kelvin test with a thickness greater than or equal to 40 μm and less than or equal to 200 μm.

The seed layer 51 is provided at a lower surface of the mold 50. The seed layer 51 may be provided at the lower surface of the mold 50 before an etching groove 52 is formed on the mold 50. Meanwhile, the lower portion of the mold 50 has a support substrate (not illustrated) to improve the handling ease of the mold 50.

The seed layer 51 is provided at the lower surface of the mold 50 by a deposition method. The seed layer 51 is formed to improve the plating property during electroplating. The seed layer 51 is formed with a thickness greater than or equal to 0.01 μm and less than or equal to 1 μm. The seed layer 51 may be composed of a single layer of titanium (Ti), copper (Cu), or nickel (Ni), or a multiple layer thereof.

Next, performed by forming the first etching groove 52 on the mold 50 is performed.

FIG. 4a is a view illustrating the mold 50 on which the first etching groove 52 is formed. FIG. 4b is a sectional view taken along line A-A′ of FIG. 4a.

The first etching groove 52 may be formed by wet-etching a part of the mold 50 of an anodic oxide film material. To this end, a photoresist is provided on an upper surface of the mold 50 and is patterned, then an anodic oxide film of the area patterned to be open reacts with an etching solution to form the first etching groove 52.

Next, forming a plating layer 53 in the first etching groove 52 is performed.

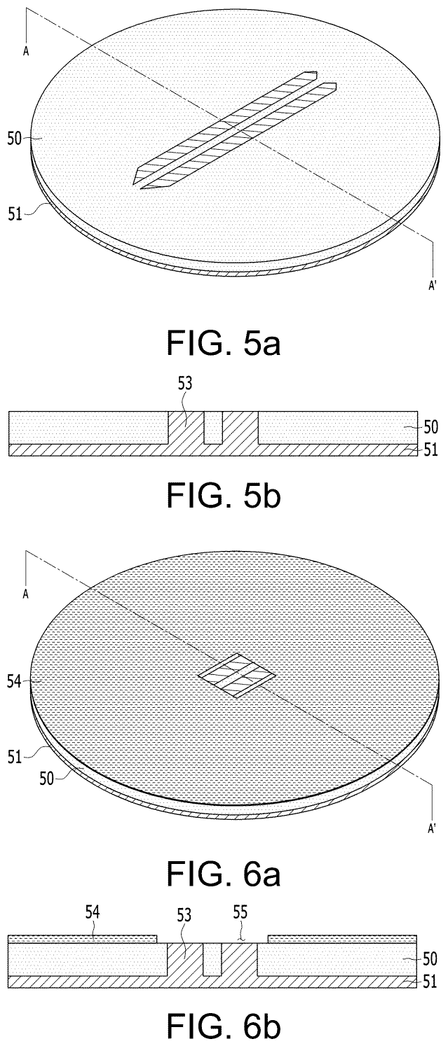

FIG. 5a is a view illustrating the mold 50 with the plating layer 53 formed in the first etching groove 52. FIG. 5b is a sectional view taken along line A-A′ of FIG. 5a.

The first electrically conductive contact pin 10 and the second electrically conductive contact pin 20 are formed by performing an electroplating process to the first etching groove 52 of the mold 50. Since the plating layer 53 is formed by growing in a thickness direction of the mold 50, each of the first electrically conductive contact pin 10 and the second electrically conductive contact pin 20 has the same sectional shapes in a thickness direction thereof.

The plating layer 53 may be formed of at least one metal selected from rhodium (Rd), platinum (Pt), iridium (Ir), palladium (Pd), nickel (Ni), manganese (Mn), tungsten (W), cobalt (Co), phosphorus (Ph), or an alloy thereof, or a palladium-cobalt (PdCo) alloy, a palladium-nickel (PdNi) alloy or a nickel-phosphorus (NiPh) alloy, a nickel-manganese (NiMn), a nickel-cobalt (NiCo), or a nickel-tungsten (NiW) alloy, copper (Cu), silver (Ag), gold (Au), or an alloy thereof.

Meanwhile, after the plating process is completed, the temperature is raised to a high temperature, and then pressure is applied to compress the plating layer 53 on which the plating process is completed, thereby densifying the plating layer 53. When a photoresist material is used as the mold, the photoresist remains around the plating layer after the plating process is completed, so the process in which temperature is raised and the pressure is applied cannot be performed. Otherwise, since the mold 50 of an anodic oxide film material is provided around the plating layer 53 on which the plating process is completed, even when the temperature is raised to a high temperature, it is possible to densify the plating layer 53 while minimizing deformation due to a low coefficient of thermal expansion of an anodic oxide film. Therefore, compared to a technique using a photoresist as a mold, it is possible to obtain the plating layer 53 that is further densified.

Next, forming a first photoresist layer 54 that is patterned on an upper portion of the mold 50 is performed.

FIG. 6a is a view illustrating the patterned first photoresist layer 54 formed on the upper portion of the mold 50. FIG. 6b is a sectional view taken along line A-A′ of FIG. 6a.

The first photoresist layer 54 is formed on the upper portion of the mold 50 on which the previous process is completed, and is patterned to form a first opening area 55. A part of the first electrically conductive contact pin 10, a part of the second electrically conductive contact pin 20, and a part of the mold 50 are exposed through the first opening area 55.

Next, forming a second etching groove 56 is performed.

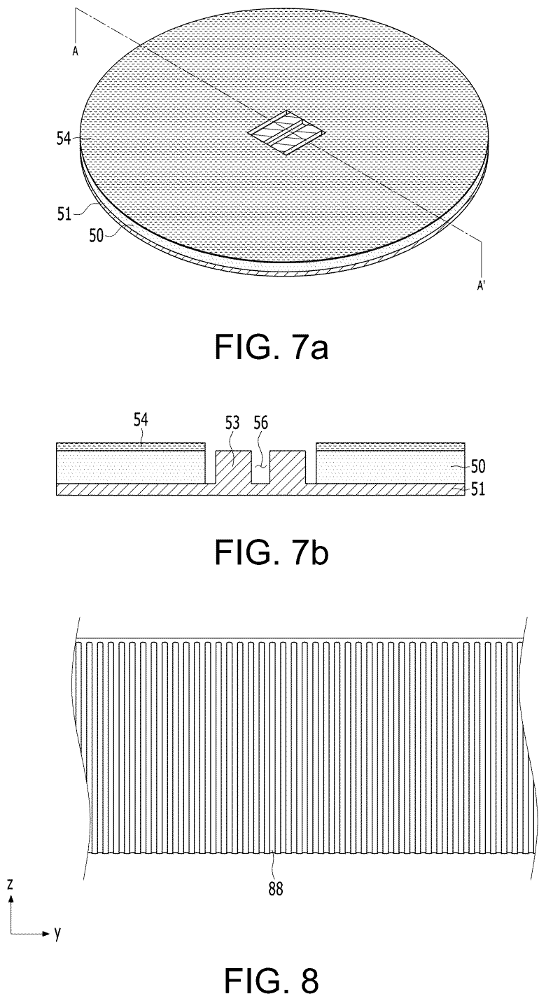

FIG. 7a is a view illustrating the second etching groove 56 formed by removing an anodic oxide film of the first opening area 54. FIG. 7b is a sectional view taken along line A-A′ of FIG. 7a.

The second etching groove 56 may be formed by wet-etching a part of the mold 50 of an anodic oxide film material. To this end, the anodic oxide film exposed through the first opening area 55 reacts to an etching solution to form the second etching groove 56. In forming the second etching groove 56, the etching solution selectively reacts only to the anodic oxide film and does not react to the plating layer 53.

As the second etching groove 56 is formed, an upper surface, a left surface, and a right surface of the first electrically conductive contact pin 10 are exposed, and an upper surface, a left surface, and a right surface of the second electrically conductive contact pin 20 are exposed.

FIG. 8 is a view illustrating a side surface of the first electrically conductive contact pin 10 having a micro trench 88. Also, a side surface of the second electrically conductive contact pin 20 has the micro trench 88 identically to FIG. 8. Therefore, the description of FIG. 8 described below is based on the first electrically conductive contact pin 10, but the micro trench 88 provided on a side surface of the second electrically conductive contact pin 20 is also formed with the same configuration described below.

A side surface of the first electrically conductive contact pin 10 has the micro trench 88 having a corrugated shape in which hills and valleys each having a depth greater than or equal to 20 nm and less than or equal to 1 μm are repeatedly arranged along a side surface of the first electrically conductive contact pin 10 in a direction perpendicular to the thickness direction of the first electrically conductive contact pin 10.

The micro trench 88 is formed by extending long in the thickness direction of the first electrically conductive contact pin 10 on a side surface of the first electrically conductive contact pin 10. In other words, the extension direction of each of the hill and valley in the micro trench 88 is the thickness direction of the first electrically conductive contact pin 10. Herein, the thickness direction of the first electrically conductive contact pin 10 is a direction in which the plating layer 53 grows during electroplating.

The micro trench 88 has a range of depth greater than or equal to 20 nm and less than or equal to 1 μm, and a range of width greater than or equal to 20 nm and less than or equal to 1 μm. Herein, the micro trench 88 is caused by the pores formed when the anodic oxide film mold is manufactured, and each of the width and the depth of the micro trench 88 has a value less than or equal to a range of a diameter of each pore of the anodic oxide film mold 50. Meanwhile, in the process of forming the first etching groove 52 on the anodic oxide film mold 50, a pore and another pore of the anodic oxide film mold 50 are partially collapsed together by the etching solution so that the micro trench 88 having a larger depth range than the diameter range of each pore formed in anodizing may be formed in a part or more.

The anodic oxide film mold 50 includes numerous pores, at least a part of the anodic oxide film mold 50 is etched to form the first etching groove 52, and the plating layer 53 is formed by electroplating inside the first etching groove 52. Therefore, a side surface of the first electrically conductive contact pin 10 includes the micro trench 88 formed while being brought into contact with the pores of the anodic oxide film mold 50.

The micro trench 88 as described above has a corrugated shape composed of hills and valleys with a depth greater than or equal to 20 nm and less than or equal to 1 μm repeated in the direction perpendicular to the thickness direction, which results in an effect of expanding a surface area of a side surface of each of the first electrically conductive contact pin 10 and the second electrically conductive contact pin 20. As the micro trench 88 formed on a side surface of each of the first electrically conductive contact pin 10 and the second electrically conductive contact pin 20 is provided, a surface area where a current flows increases by a skin effect, and a density of the current flowing along each of the first electrically conductive contact pin 10 and the second electrically conductive contact pin 20 increases to improve the electrical properties (specifically, high-frequency property) of the contact pin assembly 100 for a Kelvin test. Furthermore, as the micro trench 88 is provided, heat generated from each of the first electrically conductive contact pin 10 and the second electrically conductive contact pin 20 may be quickly dissipated, so that a temperature increase of the contact pin assembly 100 for a Kelvin test may be suppressed.

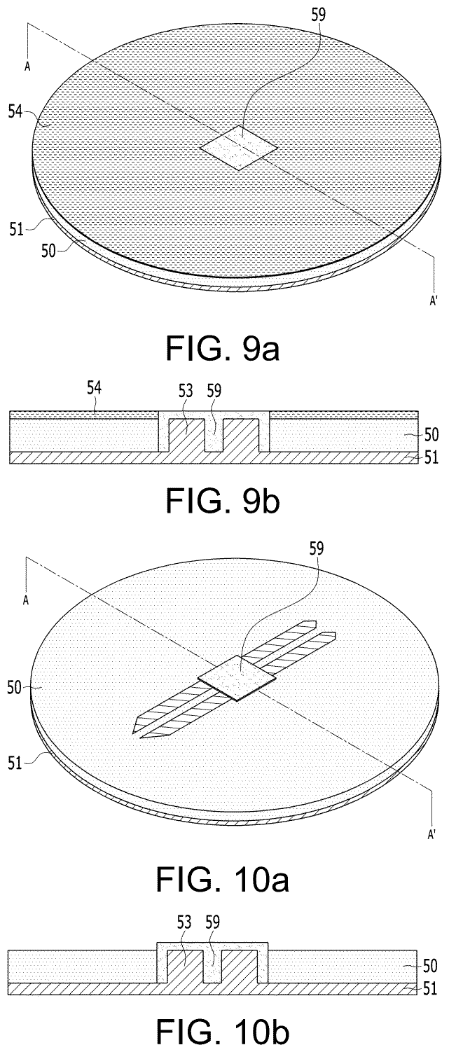

Next, filling an insulating material 59 into the second etching groove 56 is performed. FIG. 9a is a view illustrating the second etching groove 56 filled with the insulating material 59. FIG. 9b is a sectional view taken along line A-A′ of FIG. 9a.

The insulating material 59 may be formed by hardening a resin composition for forming thermoplastic polyimide, and the resin includes one or more resins selected from a group consisting of a polyimide, polyamide, polyamide-imide, and polyamic acid resin, but is not limited thereto.

Next, removing the first photoresist layer 54 is performed. FIG. 10a is a view illustrating the state of removing the first photoresist layer 54. FIG. 10b is a sectional view taken along line A-A′ of FIG. 10a.

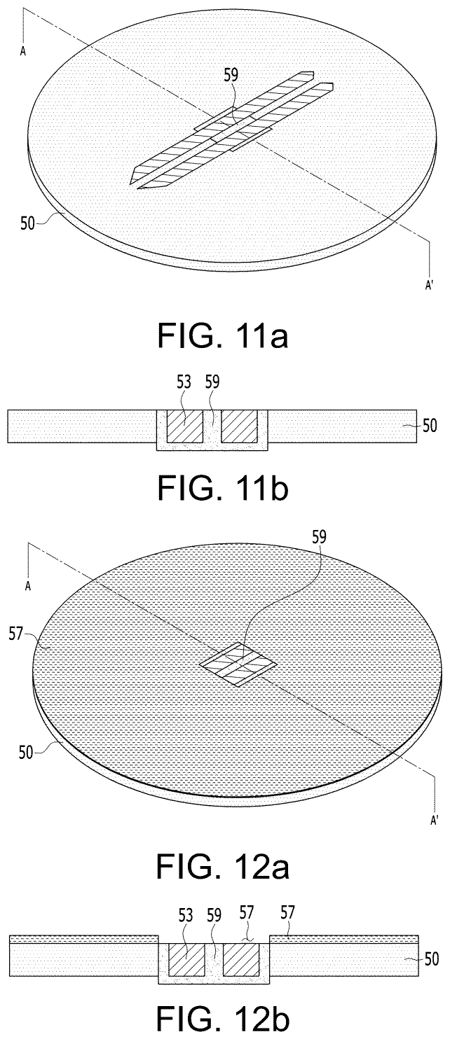

Next, turning upside down a semi-finished product on which the previous processes are completed is performed. FIG. 11a is a view illustrating an upside-down turned semi-finished product. FIG. 11b is a sectional view taken along line A-A′ of FIG. 11a.

Next, forming a second photoresist layer 57 on an upper surface is performed. FIG. 12a is a view illustrating the second photoresist layer 57 formed on the upper surface. FIG. 12b is a sectional view taken along line A-A′ of FIG. 12a.

The second photoresist layer 57 is formed and patterned to form the second opening area 58. A part of the first electrically conductive contact pin 10, a part of the second electrically conductive contact pin 20, and a part of the insulating material 59 are exposed through the second opening area 58.

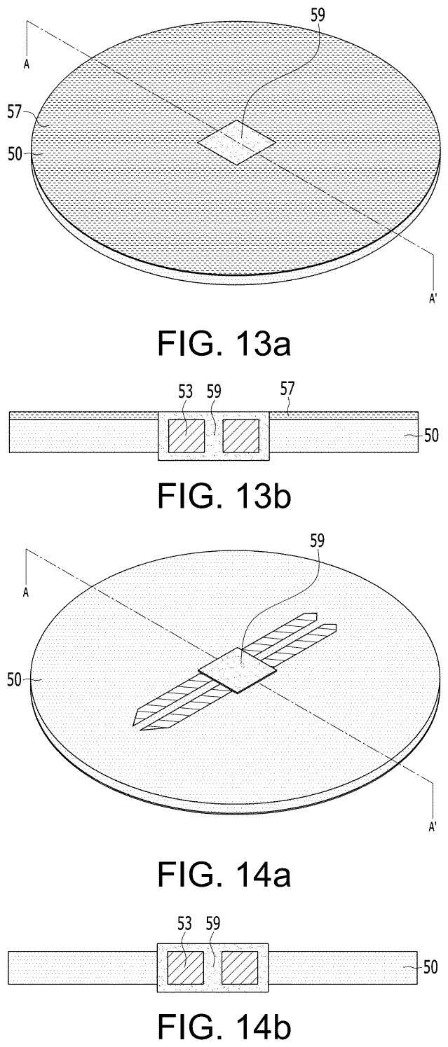

Next, filling the insulating material 59 into the second opening area 58 is performed. FIG. 13a is a view illustrating the second opening area 58 filled with the insulating material 59. FIG. 13b is a sectional view taken along line A-A′ of FIG. 13a. The insulating material 59 formed in the second opening area 58 is the same as the insulating material 59 formed previously. The insulating material 59 filled in the second opening area 58 is integrated with the insulating material formed previously.

Next, removing the second photoresist layer 57 is performed. FIG. 14a is a view illustrating the state of removing the second photoresist layer 57. FIG. 14b is a sectional view taken along line A-A′ of FIG. 14a.

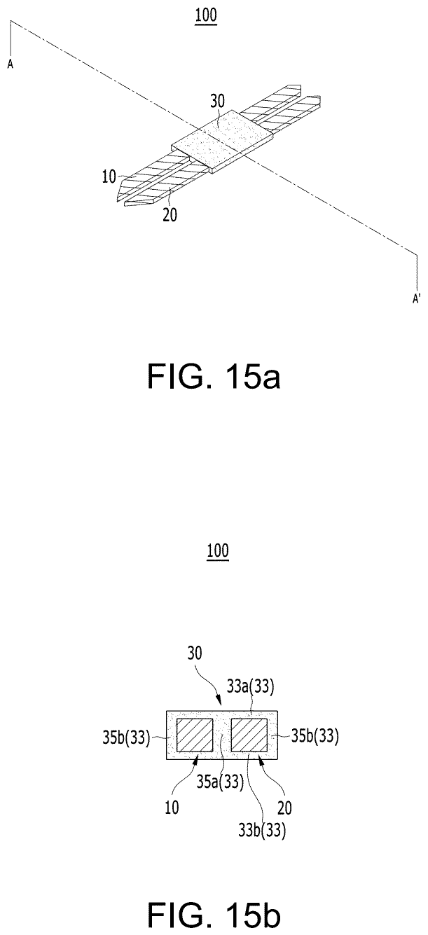

Next, removing the mold 50 of an anodic oxide film material is performed. FIG. 15a is a view illustrating the state of removing the mold 50 of an anodic oxide film material. FIG. 15b is a sectional view taken along line A-A′ of FIG. 15a.

Through the above-described process, manufacturing of the contact pin assembly 100 for a Kelvin test including the first electrically conductive contact pin 10; the second electrically conductive contact pin 20; and the insulating part 30 provided between the first electrically conductive contact pin 10 and the second electrically conductive contact pin 20 and insulating the first electrically conductive contact pin 10 and the second electrically conductive contact pin 20 from each other is completed.

With the micro trench 88 formed on a side surface of the first electrically conductive contact pin 10 and a side surface of the second electrically conductive contact pin 20, the contact pin assembly 100 for a Kelvin test according to the first embodiment has an improved coupling force between the first electrically conductive contact pin 10 and the insulating part 30 and an improved coupling force between the second electrically conductive contact pin 20 and the insulating part 30. Therefore, even when a shear force is generated on a boundary surface between the first electrically conductive contact pin 10 and the insulating part 30 and a boundary surface between the second electrically conductive contact pin 20 and the insulating part 30 to separate the first electrically conductive contact pin 10, the insulating part 30, and the second electrically conductive contact pin 20 from each other, it is possible to efficiently prevent the first electrically conductive contact pin 10 and the second electrically conductive contact pin 20 from being separated from the insulating part 30 by provision of the micro trench 88.

The contact pin assembly 100 for a Kelvin test according to the first embodiment is formed into one member as the first electrically conductive contact pin 10 and the second electrically conductive contact pin 20 are coupled to each other with the insulating part 30, so it is possible to simultaneously insert the first electrically conductive contact pin 10 and the second electrically conductive contact pin 20 into one housing hole H. Accordingly, it is possible to reduce a spacing distance between the first electrically conductive contact pin 10 and the second electrically conductive contact pin 20, which enables the contact pin assembly 100 for a Kelvin test to correspond to high-density integration of the inspection object. Furthermore, since the number of the housing holes H to be formed on the support plate GP may be reduced by half, a problem in that the rigidity of a support plate GP is deteriorated can be solved.

### Modification of First Embodiment

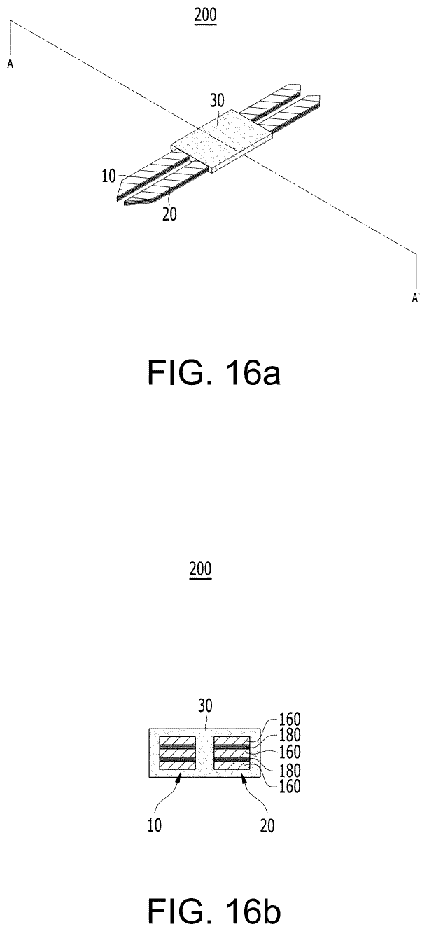

FIGS. 16a and 16b are views illustrating modifications of the contact pin assembly 100 for a Kelvin test according to the exemplary first embodiment of the present disclosure.

As illustrated in FIGS. 16a and 16b, the contact pin assembly 200 for a Kelvin test differs from the first embodiment only in that each of the first electrically conductive contact pin 10 and the second electrically conductive contact pin 20 includes multiple metal layers stacked to each other, and the rest of the structure is the same.

The multiple metal layers include the first metal layer 160 and the second metal layer 180. The first metal layer 160 has relatively higher wear resistance than the second metal layer 180 and, preferably, may be formed of a metal selected from rhodium (Rd), platinum (Pt), iridium (Ir), palladium (Pd), nickel (Ni), manganese (Mn), tungsten (W), cobalt (Co), phosphorus (Ph), or an alloy thereof, or palladium-cobalt (PdCo) alloy, palladium-nickel (PdNi) alloy or nickel-phosphorus (NiPh) alloy, nickel-manganese (NiMn), nickel-cobalt (NiCo), or nickel-tungsten (NiW) alloy. The second metal layer 180 has relatively higher electric conductivity than the first metal layer 160 and, preferably, may be formed of a metal selected from copper (Cu), silver (Ag), gold (Au), or an alloy thereof.

The first metal layer 160 may be provided at an upper surface and a lower surface in the thickness direction of each of the first electrically conductive contact pin 10 and the second electrically conductive contact pin 20, and the second metal layer 180 is provided between the first metal layers 160. For example, each of the first electrically conductive contact pin 10 and the second electrically conductive contact pin 20 may be provided such that the first metal layer 160, the second metal layer 180, and the first metal layer 160 are alternatively stacked in order, and the number of stacked layers may be 3 layers.

For example, the first metal layer 160 is made of a palladium-cobalt (PdCo) alloy, and the second metal layer 180 is made of copper (Cu). Therefore, a palladium-cobalt (PdCo) alloy and copper (Cu) are alternatively stacked to form 3 or more metal layers. Otherwise, the first metal layer 160 is made of a palladium-cobalt (PdCo) alloy or rhodium (Rd), and the second metal layer 180 is made of copper (Cu). Therefore, a palladium-cobalt (PdCo) alloy, copper (Cu), rhodium (Rd), copper (Cu), and a palladium-cobalt (PdCo) alloy are stacked to form 5 or more metal layers.

As multiple metal layers are stacked, the elasticity, wear resistance, and/or electric conductivity of the contact pin assembly 200 for a Kelvin test arranged into the narrower pitch can be improved. In other words, since the contact pin assembly 200 uses a structure in which multiple metal layers are stacked, even when the contact pin assembly 200 for a Kelvin test is arranged into a narrow pitch, it is possible to prevent wear resistance or electric conductivity from being deteriorated and to provide high-elastic mechanical properties.

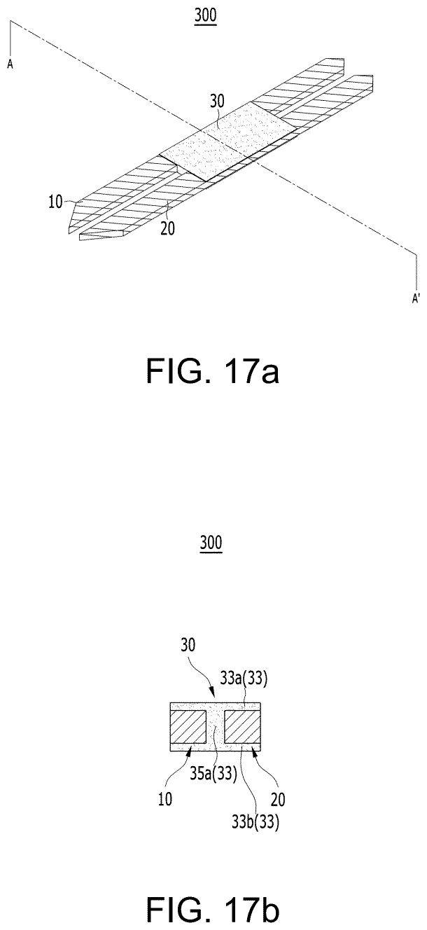

FIGS. 17a and 17b are views illustrating modifications of the contact pin assembly 100 for a Kelvin test according to the exemplary first embodiment of the present disclosure.

As illustrated in FIGS. 17a and 17b, the contact pin assembly 300 for a Kelvin test differs from the first embodiment only in an area where the insulating part 30 covers and the remain of the structure is the same.

The insulating part 30 illustrated in FIGS. 17a and 17b includes the surface insulating part 33 provided each of an upper surface and a lower surface of the first electrically conductive contact pin 10 and each of an upper surface and a lower surface of the second electrically conductive contact pin 20, and the side surface insulating part 35 provided between the first electrically conductive contact pin 10 and the second electrically conductive contact pin 20. The insulating part 30 illustrated in FIGS. 17a and 17b differs from the first embodiment in that the outside surface insulating part 35 is not provided.

As the side surface insulating part 35 is not provided, compared to the contact pin assembly 100 for a Kelvin test according to the first embodiment, there is an effect that heat dissipation properties through a side surface of the contact pin assembly 300 for a Kelvin test are improved.

### Second Embodiment

Next, a second embodiment according to the present disclosure will be described. However, embodiments described below will mainly be described to focus on characteristic components compared to the first embodiment, and the descriptions of the components that are the same or similar to the first embodiment are omitted if possible.

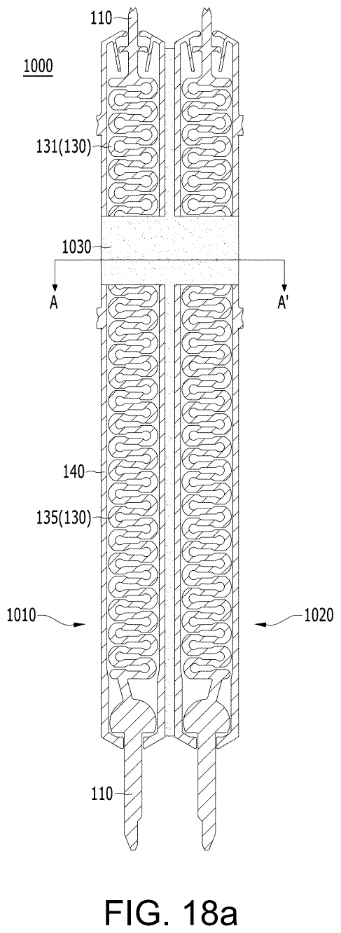

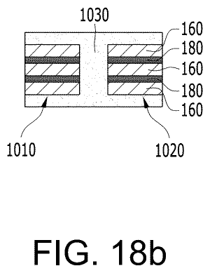

Hereinafter, referring to FIGS. 18a to 21, the contact pin assembly 1000 for a Kelvin test according to the exemplary second embodiment of the present disclosure will be described.

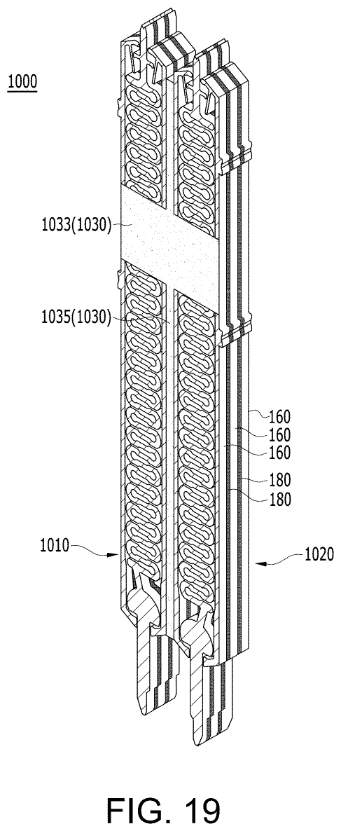

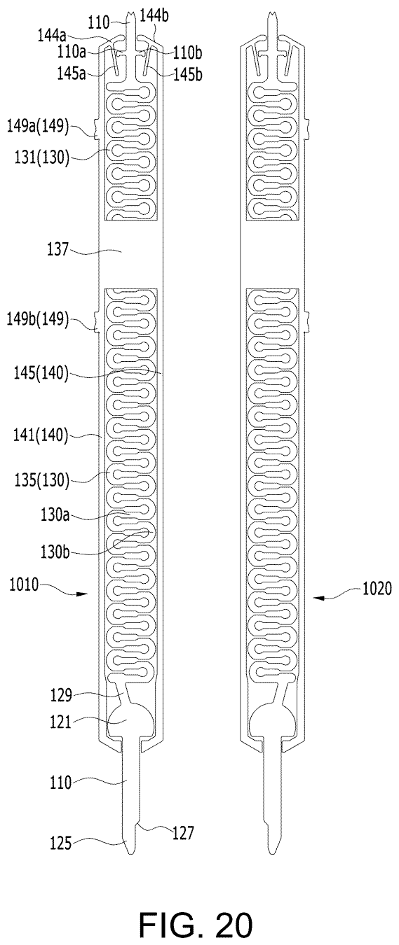

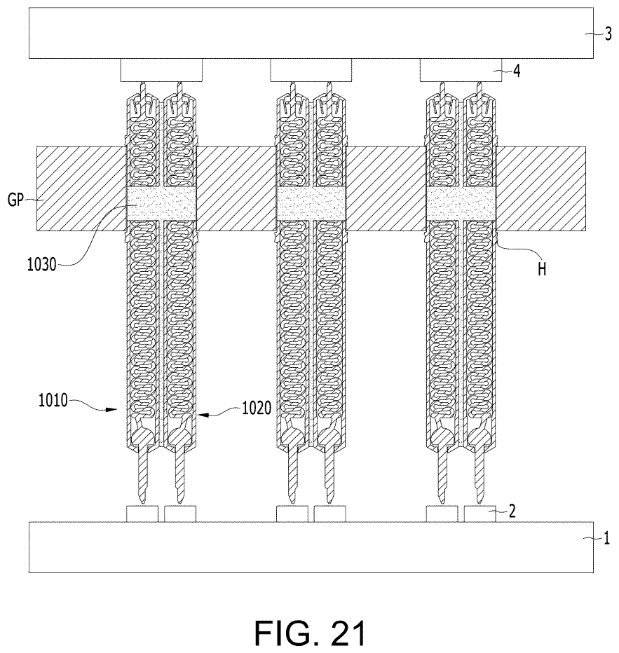

FIG. 18a is a plan view illustrating the contact pin assembly for a Kelvin test according to an exemplary second embodiment of the present disclosure. FIG. 18b is a sectional view illustrating taken alone line A-A′ of FIG. 18a. FIG. 19 is a perspective view of the contact pin assembly for a Kelvin test according to an exemplary second embodiment of the present disclosure. FIG. 20 is a view only illustrating a pair of electrically conductive contact pins of the contact pin assembly for a Kelvin test according to the exemplary second embodiment of the present disclosure. FIG. 21 is a view illustrating a Kelvin test using the contact pin assembly for a Kelvin test according to the exemplary second embodiment of the present disclosure.

The contact pin assembly 1000 for a Kelvin test according to the second embodiment is electrically connected to one electrode 2 provided at the inspection object 1 and each of two lands 4 provided at a circuit board 3.

According to the first embodiment, the contact pin assembly 1000 for a Kelvin test includes the first electrically conductive contact pin 1010, the second electrically conductive contact pin 1020, and the insulating part 1030. The insulating part 1030 is provided between the first electrically conductive contact pin 1010 and the second electrically conductive contact pin 1020 and insulates the first electrically conductive contact pin 1010 and the second electrically conductive contact pin 1020 from each other.

Each of the first electrically conductive contact pin 1010 and the second electrically conductive contact pin 1020 is provided such that multiple metal layers are stacked. The multiple metal layers include the first metal layer 160 and the second metal layer 180. The first metal layer 160 is a metal having relatively higher wear resistance than the second metal layer 180 and, preferably, may be a metal selected from rhodium (Rd), platinum (Pt), iridium (Ir), palladium (Pd), nickel (Ni), manganese (Mn), tungsten (W), cobalt (Co), phosphorus (Ph) or an alloy thereof, or palladium-cobalt (PdCo) alloy, palladium-nickel (PdNi) alloy or nickel-phosphorus (NiPh) alloy, nickel-manganese (NiMn), nickel-cobalt (NiCo), or nickel-tungsten (NiW) alloy. The second metal layer 180 has relatively higher electric conductivity than the first metal layer 160 and, preferably, may be formed of a metal selected from copper (Cu), silver (Ag), gold (Au), or an alloy thereof.

The first metal layer 160 may be provided at an upper surface and a lower surface in the thickness direction of each of the first electrically conductive contact pin 1010 and the second electrically conductive contact pin 1020, and the second metal layer 180 is provided between the first metal layers 160. For example, each of the first electrically conductive contact pin 1010 and the second electrically conductive contact pin 1020 may be provided such that the first metal layer 160, the second metal layer 180, and the first metal layer 160 are alternatively stacked in order, and the number of stacked layers may be 3 layers.

The first electrically conductive contact pin 1010 and the second electrically conductive contact pin 1020 are arranged in a transversely symmetric form based on the insulating part 30. The structure of the first electrically conductive contact pin 1010 described below is used in the second electrically conductive contact pin 1020, so the description thereof will be based on the first electrically conductive contact pin 1010 and the structure described in the first electrically conductive contact pin 1010 will be omitted description in the second electrically conductive contact pin 1020.

The first electrically conductive contact pin 1010 includes: a first plunger 110 located at a first end portion of the first electrically conductive contact pin 1010 and used as a first contact point at an end portion thereof; a second plunger 120 located at a second end portion of the first electrically conductive contact pin 1010 and used as a second contact point at an end portion thereof; an elastic part 130 enabling the first plunger 110 and the second plunger 120 to be elastically displaced in a longitudinal direction of a probe pin 100; and a support part 140 guiding the elastic part 130 to be compressed and stretched in the longitudinal directing of the probe pin 100, and provided outside the elastic part 130 in the longitudinal direction of the probe pin 100 to prevent the elastic part 130 from being bent horizontally while being compressed or from being bent and buckled.

The first contact point of the first plunger 110 is brought into contact with the upper contact object, and the second plunger 120 is brought into contact with the lower contact object. Referring to FIG. 21, the first plunger 110 is brought into contact with the land 4 of the circuit board 3, and the second plunger 120 is brought into contact with each electrode 2 of the inspection object 1. Meanwhile, on the other hand, the first plunger 110 may be brought into contact with each electrode 2 of the inspection object 1, and the second plunger 120 may be brought into contact with the land 4 of the circuit board 3.

The elastic part 130 includes: a first elastic part 131 connected to the first plunger 110; a second elastic part 135 connected to the second plunger 120; and a middle fixation part 137 connected to the first elastic part 131 and the second elastic part 135 while being provided between the first elastic part 131 and the second elastic part 135, and integrated with the support part 140. The elastic part 130 has sectional shapes in a thickness direction of the first electrically conductive contact pin 1010 which are the same in all thickness sections. Furthermore, the thickness of the elastic part 130 is entirely the same. Each of the first and second elastic parts 131 and 135 is formed of a plate-shaped plate having a substantial width (t) repeatedly bent into a S-shape, and the substantial width (t) of the plate-shaped plate is entirely the same. A ratio of the substantial width and the thickness of the plate-shaped plate is a range greater than or equal to 1:5 and less than or equal to 1:30.

Before the first electrically conductive contact pin 1010 inspects the inspection object 1, the first plunger 110 is brought into contact with the land 4 of the circuit board 3, the first elastic part 130 is compressed and deformed in the longitudinal direction of the first electrically conductive contact pin 1010, and the second plunger 120 is not in contact with the inspection object 1. In a process in which the first electrically conductive contact pin 1010 inspects the inspection object 1, the second plunger 120 is brought into contact with each electrode 2 of the inspection object 1, and the second elastic part 135 is compressed and deformed.

A first end of the first plunger 110 is a free end, and a second end is connected to the first elastic part 131 so that vertical movement is elastically possible by a contact pressure. A first end of the second plunger 120 is a free end, and a second end is connected to the second elastic part 135 so that vertical movement is elastically possible by contact pressure.

A first end of the first elastic part 131 is connected to the first plunger 110, and a second end thereof is connected to the middle fixation part 137. A first end of the second elastic part 135 is connected to the second plunger 120, and a second end thereof is connected to the middle fixation part 137.

The support part 140 includes a first support part 141 provided at the left space of the elastic part 130 and a second support part 145 provided at the right space of the elastic part 130.

To catch and fix the support part 140 by a support plate GP, an outer wall of the support part 140 includes a locking part 149. The locking part 149 includes an upper locking part 149a caught by an upper surface of the support plate GP, and a lower locking part 149b caught by a lower surface of the support plate GP1.

The middle fixation part 137 is formed by extending in a width direction of the first electrically conductive contact pin 1010 and connects the first support part 141 and the second support part 145 to each other.

The first elastic part 131 is provided at an upper portion based on the middle fixation part 137, and the second elastic part 135 is provided at a lower portion based on the middle fixation part 137. Based on the middle fixation part 137, the first elastic part 131 and the second elastic part 135 are deformed by being compressed or stretched. The middle fixation part 137 is fixed by the first and second support parts 141 and 145 and serves to suppress position movement of the first and second support parts 141 and 145 when the first and second elastic parts 131 and 135 are compressed and deformed.

The first support part 141 and the second support part 145 are formed in the longitudinal direction of the first electrically conductive contact pin 1010, and the first support part 141 and the second support part 145 are integrally connected to the middle fixation part 137 formed by extending in the width direction of the first electrically conductive contact pin 1010. Furthermore, as the first and second elastic parts 131 and 135 are integrally connected to each other through the middle fixation part 137, the first electrically conductive contact pin 1010 has overall one body.

Each of the first and second elastic parts 131 and 135 is formed of a plurality of linear parts 130a and a plurality of curved parts 130b alternatively connected to each other. Each linear part 130a connects left and right adjacent curved parts 130b to each other, and each curved part 130b connects upper and lower adjacent linear parts 130a to each other. Each curved part 130b is provided in a circular arc shape.

Each linear part 130a is disposed at a center portion of each of the first and second elastic parts 131 and 135, and each curved part 130b is disposed at an outer portion of each of the first and second elastic parts 131 and 135. Each linear part 130a is provided in parallel to a width direction so that deformation of each curved part 130b depending on a contact pressure is easily performed.

A portion of each of the first and second elastic parts 131 and 135 connected to the middle fixation part 137 is a curved part 130b of each of the first and second elastic parts 131 and 135. Accordingly, each of the first, second elastic parts 131 and 135 maintains elasticity to the middle fixation part 137.

The first elastic part 131 needs enough compression for first plungers 110 of a plurality of first electrically conductive contact pins 100 to be brought into stably contact with respective upper contact objects. On the other hand, the second elastic part 135 needs enough compression for second plungers 120 of a plurality of probe pins 100 to be brought into stably contact with respective lower contact objects. Therefore, a spring coefficient of the first elastic part 131 and a spring coefficient of the second elastic part 135 are different from each other. For example, the length of the first elastic part 131 and the length of the second elastic part 135 are provided differently from each other. Furthermore, the longitudinal length of the second elastic part 135 may be formed longer than the longitudinal length of the first elastic part 131.

The opposite ends of the first support part 141 and the opposite ends of the second support part 145 are close and spaced apart from each other to form openings. The openings include an upper opening through which the first plunger 110 may pass vertically and a lower opening through which the second plunger 120 may pass vertically. The upper opening and the lower opening prevent the first and second plungers 110 and 120 from excessively protruding toward the support part 140 by restoring forces of the first and second elastic parts 131 and 135.

The first support part 141 includes a first door part 144a extending toward the upper opening, and the second support part 145 includes a second door part 144b extending toward the upper opening. The first door part 144a and the second door part 144b are spaced apart from each other in opposite directions to form the upper opening at a space therebetween. The opening width of the upper opening is formed smaller than the transverse length of the linear part 130a of the first elastic part 131

The first plunger 110 is connected to a linear part 130a of the first elastic part 131 and has a rod shape formed long in the longitudinal direction of the first electrically conductive contact pin 100. The first plunger 110 may pass vertically through the upper opening formed by the first support part 141 and the second support part 145. Furthermore, the transverse length of the linear part 130a of the first elastic part 131 is formed longer than the width of the upper opening, so the linear part 130a of the first elastic part 131 cannot pass through the upper opening. Accordingly, an increased stroke of the first plunger 110 is limited.

As the opposite ends of the first support part 141 and the opposite ends of the second support part 145 are close and spaced apart from each other to form the upper opening through which the first plunger 110 can pass vertically. When the first plunger 141 is moved downward inside the support part 140, while the opening width of the upper opening is reduced, the first and second support parts 141 and 145 and the first plunger 110 are brought into contact with each other to form additional contact points.

The first support part 141 includes a first extension part 145a extending toward the inside space of the support part 140, and the second support part 145 includes a second extension part 145b extending toward the inner space of the support part 140.

The first extension part 145a is connected to the first door part 144a. A first end of the first extension part 145a is connected to the first door part 144a and a second end of the first extension part 145a extends toward the inner space of the support part 140 to be a free end.

The second extension part 145b is connected to the second door part 144b. A first end of the second extension part 145b is connected to the second door part 144b and a second end of the first extension part 145a extends toward the inner space of the support part 140 to be a free end.

The first plunger 110 includes a first protruding piece 110a extending toward the first extension part 145a and a second protruding piece 110b extending toward the second extension part 145b. When the first plunger 110 is lowered by a pressure force, the first protruding piece 110a and the second protruding piece 110b may be brought into contact with the first extension part 145a and the second extension part 145b, respectively.

When the first plunger 110 is lowered, the first protruding piece 110a and the second protruding piece 110b may be brought into contact with the first extension part 145a and the second extension part 145b to form additional contact points.

As the first extension part 145a and the second extension part 145b are formed to be inclined, when the first plunger 110 is lowered vertically, the first protruding piece 110a and the second protruding piece 110b press the first extension part 145a and the second extension part 145b, and a space between the first door part 144a and the second door part 144b is reduced. In other words, as the first plunger 110 is lowered, the first door part 144a and the second door part 144b are deformed to be closer to each other to reduce the opening width of the upper opening. As described above, when the first plunger 110 is vertically lowered in the support part 140, the opening width of the upper opening is reduced so that the first and second support parts 141 and 145 and the first plunger 110 are brought into contact with each other to form additional contact points.

When the first plunger 110 is lowered, the first and second protruding pieces 110a and 110b and the first and second extension parts 145a and 145b are primarily brought into contact with each other to form additional contact points. When the first plunger 110 is additionally lowered, the first and second door parts 144a and 144b and the first plunger 110 are secondarily brought into contact with each other to form additional contact points. As described above, the first plunger 110 is vertically lowered, and an additional current path is formed between the first plunger 110 and the support part 140. The additional current path does not pass through the elastic part 130 and is directly formed from the support part 140 to the first plunger 110. As the additional current path is formed, more stable electrical contact is possible.

The opening width of the upper opening is reduced in proportion to the vertically lowering distance of the first plunger 110. Furthermore, a lowering pressure is applied to the first plunger 110 even after the first and second door parts 144a and 144b are in contact with the first plunger 110, a frictional force between the first and second door parts 144a and 144b and the first plunger 110 is further increased. The increased frictional force prevents the first plunger 110 from being excessively lowered. Accordingly, it is possible to prevent the elastic part (more specifically, the first elastic part 131) from being excessively compressed and deformed.

An upper portion of the second plunger 120 is connected to the second elastic part 135 and an end passes through the lower opening.

The second plunger 120 includes a connection part 129 connected to the elastic part 130, a protruding tip 125 providing the second contact point, and an inner body 121 provided between the connection part 129 and the protruding tip 125 and prevented from being separated outward of the support part 140.

A first end of the connection part 129 is connected to the elastic part 130, more specifically, to the second elastic part 135, and a second end of the connection part 129 is connected to the inner body 121.

The second plunger 120 repeatedly performs upward and downward movements. At this time, the support part 140 located at the left and right sides and the second plunger 120 are brought into sliding-contact with each other. To minimize a sliding frictional force between the second plunger 120 and the support part 140, the inner body 121 has a hemisphere shape based on the plan view. A frictional resistance between the inner body 121 and the support part 140 is minimized as the inner body 121 has a hemisphere shape.

The inner body 121 is a portion located inside the support part 140, and a transverse length of a lower surface of the inner body 121 is formed larger than the opening width of the lower opening to prevent the inner body 121 from being separated from the support part 140.

The protruding tip 125 of the second plunger 120 includes a step part 127. The step part 127 is formed such that the width of the second plunger 120 is increased, at a portion of the second plunger 120 protruding from the support part 140, from the second contact point toward the lower opening 143b.

Debris of an oxide film layer occurs, the debris being generated in a process in which the wiping operation of the second plunger 120 is performed. The debris is electrodeposited and held together, and the debris is induced to be caught by the step part 127 and naturally fall, and is prevented from being continuously grown. Furthermore, the step part 127 prevents the debris from being moved inward of the support part 140.

The second plunger 120 performs the wiping operation at the second contact point while being moved vertically upward in the support part 140. To allow the second contact point of the second plunger 120 to perform the wiping operation when the second plunger 120 is moved upward, the second elastic part 135 of the elastic part 130 is connected to the second plunger 120 while being eccentric from a shaft line direction of the second plunger 120.

The connection part 129 is connected to the second elastic part 135 and a spherical surface of the inner body 121 at inclined angles. A first end of the connection part 129 is connected to a spherical surface of the inner body 121 at a position of the shaft line or a position close to the shaft line of the second plunger 120, and a second end of the connection part 129 is connected to the second elastic part 135 at a position farther from the shaft line than the first end. Specifically, the first end of the connection part 129 is connected to the inner body 121 at a position of the shaft line of the inner body 121, and the second end of the connection part 129 is connected to the second elastic part 135 at a position of the curved part 130b of the second elastic part 135.

When the second plunger 120 is moved upward, the inner body 121 has a biased repulsive force by the connection part 129 connected from an upper surface of the inner body 121 to the second elastic part 135 at an inclination. Accordingly, when the second plunger 120 is moved upward vertically by a pressure force, the inner body 121 receives eccentric resistance. The eccentric resistance is applied to the inner body 121 at the upper side to generate a rotational moment in the inner body 121. As a result, the protruding tip 125 of the second plunger 120 maintains an appropriate contact pressure to the inspection object and tilts at the same time, thereby performing the wiping operation on the inspection object.

The second plunger 120 causes a crack in an oxide film layer while maintaining an appropriate contact pressure and tilting at the same time, and a conductive material layer of the electrode 2 is exposed through the crack to be brought into contact with the protruding tip 125. Accordingly, an electrical connection is performed. Furthermore, with the wiping operation, it is possible to minimize damage to the electrode 2 and prevent an excessive amount of debris from being caused, so there is an effect of improving the usage time of the first electrically conductive contact pin 100.

The size of which the second contact point wipes on the electrode 2 of the inspection object is controllable by the size of a gap between the lower opening and the protruding tip 125. The gap between the lower opening and the protruding tip 125 is a factor determining an allowable tilting angle. As the gap between the lower opening and the protruding tip 125 is increased, the tilting angle of the second contact point of the protruding tip 125 is increased. As the gap between the lower opening and the protruding tip 125 is reduced, the tilting angle of the second contact point of the protruding tip 125 is reduced.

The wiping operation is performed while a repeatedly bent spring structure is compressed and deformed, which prevents the electrode 2 from receiving excessive pressure and minimize damage to the electrode 2.

The first and second plungers 110 and 120, the elastic part 130, and the support part 140 are manufactured at the same time by a plating process to be provided integrally. For the first electrically conductive contact pin 1010, plate-shaped plates is entirely connected to be integrally to form the first and second plungers 110 and 120, the elastic part 130, and the support part 140.

The insulating part 1030 simultaneously has a coupling function of integrally coupling the first electrically conductive contact pin 1010 and the second electrically conductive contact pin 1020 to each other and an insulating function of insulating the first electrically conductive contact pin 1010 and the second electrically conductive contact pin 1020 from each other.

The insulating part 1030 is thermoplastic polyimide (TPI), and thermoplastic polyimide includes hardened resin composition for forming thermoplastic polyimide including one or more types of resins selected from a group consisting of polyimide, polyamide, polyamide-imide, and polyamic acid resin. However, a material of the insulating part 30 is not limited thereto and may include as long as it can achieve both the coupling function and the insulating function of the first electrically conductive contact pin 1010 and the second electrically conductive contact pin 1020 at the same time.

The insulating part 1030 is formed to entirely wrap the first electrically conductive contact pin 1010 and the second electrically conductive contact pin 1020 in a partial region between opposite ends of the first electrically conductive contact pin 1010 and the second electrically conductive contact pin 1020. As a result, in the region with the insulating part 30, the first electrically conductive contact pin 10 and the second electrically conductive contact pin 20 are prevented from being exposed.

The insulating part 1030 includes a surface insulating part 1033 and a side surface insulating part 1035. The surface insulating part 1033 and the side surface insulating part 1035 are formed to be integrally connected to each other.

The surface insulating part 1033 is provided on at least one of upper and lower surfaces of at least one of the first and second electrically conductive contact pins 1010 and 1020.

The side surface insulating part 1035 is provided between the first electrically conductive contact pin 1010 and the second electrically conductive contact pin 1020. More specifically, the side surface insulating part 1035 is provided between the support part 140 provided in the first electrically conductive contact pin 1010 and the support part 140 provided in the second electrically conductive contact pin 1020. The side surface insulating part 1035 is provided not only on an inner side surface of the first electrically conductive contact pin 1010 and an inner side surface of the second electrically conductive contact pin 1020, not illustrated in the drawing, but also on an outer side surface of the first electrically conductive contact pin 1010 and an outer side surface of the second electrically conductive contact pin 1020.

The insulating part 1030 is provided to correspond to positions of the middle fixation part 137 of the first electrically conductive contact pin 1010 and the middle fixation part 137 of the second electrically conductive contact pin 1020.

The surface insulating part 1033 is provided at least one of upper and lower surfaces of at least one of the middle fixation part 137 provided in the first electrically conductive contact pin 1010 and the middle fixation part 137 provided in the second electrically conductive contact pin 1020. The side insulating part 1035 is provided between the support part 140 of the first electrically conductive contact pin 1010 and the support part 140 of the second electrically conductive contact pin 1020.

The side surface insulating part 1035 extends in the longitudinal direction by a longitudinal extending length of the support part 140 of each of the first electrically conductive contact pin 1010 and the second electrically conductive contact pin 1020 to prevent the support part 140 of the first electrically conductive contact pin 1010 and the support part 140 of the second electrically conductive contact pin 1020 from being brought into contact with each other, and may be provided between the support part 140 of the first electrically conductive contact pin 1010 and the support part 140 of the second electrically conductive contact pin 1020.

The surface insulating part 1033 is provided on a surface of the middle fixation part 137 (upper surface and/or lower surface), does not disturb elastic deformation of the elastic part 130, and minimizes separation of the side surface insulating part 1035 separating from the first electrically conductive contact pin 1010 and/or the second electrically conductive contact pin 1020.

Each of a side surface of the first electrically conductive contact pin 1010 and a side surface of the second electrically conductive contact pin 1020 includes the micro trench 88 described in the first embodiment. More specifically, the first electrically conductive contact pin 1010 and the second electrically conductive contact pin 1020 are made using the mold 50 of an anodic oxide film material. As a result, each of a side surface of the support part 140 of the first electrically conductive contact pin 1010 and a side surface of the support part 140 of the second electrically conductive contact pin 1020 includes the micro trench 88.

With the micro trench 88 formed on a side surface of the first electrically conductive contact pin 1010 and a side surface of the second electrically conductive contact pin 1020, a coupling force between the first electrically conductive contact pin 1010 and the insulating part 1030 is improved and a coupling force between the second electrically conductive contact pin 1020 and the insulating part 1030 is improved. Therefore, on a boundary surface between the first electrically conductive contact pin 1010 and the insulating part 1030 and a boundary surface between the second electrically conductive contact pin 1020 and the insulating part 1030, even when a shear force is generated to separate the first electrically conductive contact pin 1010, the insulating part 1030, and the second electrically conductive contact pin 1020 from each other, it is possible to efficiently prevent the first electrically conductive contact pin 1010 and the second electrically conductive contact pin 1020 from being separated from the insulating part 1030 by provision of the micro trench 88.

### Test Device

The contact pin assembly 100, 200, 300, 1000 for a Kelvin test according to each preferred embodiment of the present disclosure described above is provided in a test device and used to precisely measure the electrical properties of an inspection object. The test device to which the contact pin assembly 100, 200, 300, 1000 for a Kelvin test according to each preferred embodiment of the present disclosure may be used is not limited below, and includes any test device for confirming the electrical properties of an inspection object by applying electricity.

An inspection object of the test device may include a semiconductor device, a memory chip, a microprocessor chip, a logic chip, a lighting emitting device, or a combination thereof. For example, the inspection object includes a logic LSI (such as ASIC, FPGA, and ASSP), microprocessor (such as CPU and GPU), memory (DRAM, HMC (Hybrid Memory Cube), MRAM (Magnetic RAM), PCM (Phase-Change Memory), ReRAM (Resistive RAM), FeRAM (ferroelectric RAM), and flash memory (NAND flash)), semiconductor light emitting element (including LED, mini LED, micro LED, etc.), power device, analog IC (DC-AC converter and insulated gate bipolar transistor (such as acceleration sensor, pressure sensor, control point, and gyro sensor), no-wiring device (such as GPS, FM, NFC, RFEM, MMIC, and WLAN), separate device, BSI, CIS, camera module, CMOS, passive device, GAW filter, RF filter, RF IPD, APE, and BB.

The test device includes the support plate GP having a hole and the contact pin assembly 100, 200, 300, 1000 for a Kelvin test which is inserted into the housing hole H of the support plate GP to be installed at the support plate GP. More specifically, the test device includes: the contact pin assembly for a Kelvin test 100, 1000 including the first electrically conductive contact pin 10, 1010, the second electrically conductive contact pin 20, 1020, and the insulating part 30, 1030 provided between the first electrically conductive contact pin 10, 1010 and the second electrically conductive contact pin 20, 1020 and insulating the first electrically conductive contact pin 10, 1010 and the second electrically conductive contact pin 20, 1020 from each other; and the support plate GP having the housing hole H housing the contact pin assembly 100, 200, 300, 1000 for a Kelvin test therein.

Herein, the first electrically conductive contact pin 10, 1010 and the second electrically conductive contact pin 20, 1020 are simultaneously inserted into one housing hole H.

A sectional shape of the housing hole H is a quadrilateral shape, and an outer shape of a section of the contact pin assembly 100, 200, 300, 1000 for a Kelvin test is a quadrilateral shape corresponding to the shape of the housing hole H. Accordingly, while the contact pin assembly 100, 200, 300, 1000 for a Kelvin test is inserted in the housing hole H, the contact pin assembly 100, 200, 300, 1000 for a Kelvin test is prevented from being rotated in the housing hole H. Therefore, a contact error occurring when the contact pin assembly 100, 200, 300, 1000 for a Kelvin test is rotated in the housing hole H can be prevented in advance.

Although the preferred embodiments of the present disclosure have been described for illustrative purposes, those skilled in the art will appreciate that various modifications, additions and substitutions are possible, without departing from the scope and spirit of the present disclosure as disclosed in the accompanying claims.

### DESCRIPTION OF REFERENCE NUMERALS

10: first electrically conductive contact pin
20: second electrically conductive contact pin
30: insulating part
100: contact pin assembly for a Kelvin test

1. A contact pin assembly for a Kelvin test electrically connected to one electrode provided at an inspection object and two lands provided at the circuit board, respectively, the contact pin assembly comprising:
a first electrically conductive contact pin;
a second electrically conductive contact pin; and
an insulating part provided between the first electrically conductive contact pin and the second electrically conductive contact pin and insulating the first electrically conductive contact pin and the second electrically conductive contact pin from each other.

2. The contact pin assembly of claim 1, wherein the insulating part comprises:
a surface insulating part provided on at least one of upper and lower surfaces of at least one of the first and second electrically conductive contact pins; and
a side surface insulating part provided between the first electrically conductive contact pin and the second electrically conductive contact pin,
wherein the surface insulating part and the side surface insulating part are formed to be integrally connected to each other.

3. The contact pin assembly of claim 1, further comprising: a micro trench provided on a side surface of the first electrically conductive contact pin and a side surface of the second electrically conductive contact pin, the surfaces being in contact with the insulating part.

4. The contact pin assembly of claim 3, wherein the micro trench has a corrugated shape composed of a hill and a valley with a depth greater than or equal to 20 nm and less than or equal to 1 μm, the hill and the valley being repeated along the side surfaces of the first electrically conductive contact pin and the second electrically conductive contact pin.

5. The contact pin assembly of claim 1, wherein each of the first electrically conductive contact pin and the second electrically conductive contact pin is formed of a plurality of metal layers stacked in a thickness direction of each electrically conductive contact pin.

6. The contact pin assembly of claim 1, wherein each of the first electrically conductive contact pin and the second electrically conductive contact pin comprises:
a first plunger; a second plunger; an elastic part enabling the first plunger and the second plunger to be elastically displaced; and a support part guiding the elastic part so that the elastic part is compressed and stretched in a longitudinal direction of the contact pin assembly for a Kelvin test,
wherein the insulating part is provided between the support part that is provided in the first electrically conductive contact pin and the support part that is provided in the second electrically conductive contact pin.

7. The contact pin assembly of claim 6, wherein the elastic part comprises:
a first elastic part connected to the first plunger;
a second elastic part connected to the second plunger; and
a middle fixation part connected to the first elastic part and the second elastic part while being located between the first elastic part and the second elastic part, and provided integrally with the support part,
wherein the insulating part comprises:
a surface insulating part provided on at least one of upper and lower surfaces of at least one of the middle fixation part of the first electrically conductive contact pin and the middle fixation part of the second electrically conductive contact pin; and
a side surface insulating part provided between the first electrically conductive contact pin and the second electrically conductive contact pin.

8. The contact pin assembly of claim 1, wherein the insulating part is thermoplastic polyimide.

9. A Kelvin test device comprising:
a contact pin assembly for a Kelvin test, the contact pin assembly comprising: a first electrically conductive contact pin; a second electrically conductive contact pin; and an insulating part provided between the first electrically conductive contact pin and the second electrically conductive contact pin and insulating the first electrically conductive contact pin and the second electrically conductive contact pin from each other; and
a support plate in which a housing hole housing the contact pin assembly for a Kelvin test is formed.

10. The Kelvin test device of claim 9, wherein a section of the housing hole is a quadrilateral shape, and
in order to prevent the contact pin assembly for a Kelvin test from being rotated while being inserted in the housing hole, an outer shape of a section of the contact pin assembly for a Kelvin test is a quadrilateral shape corresponding to the shape of the housing hole.
